(19) United States
(12) Patent Application Publication
(10) Pub. No.: US 2013/0292733 A1
(43) Pub. Date: Nov. 7, 2013

(54) CRYSTALLINE MATERIAL, AND LIGHT-EMITTING DEVICE AND WHITE LED USING SAME

(71) Applicants: Kenji Toda, Niigata-shi (JP); Kazuyoshi Uematsu, Niigata-shi (JP); Mineo Sato, Niigata-shi (JP); Tadashi Ishigaki, Niigata-shi (JP); Yoshitaka Kawakami, Niigata-shi (JP); Tetsu Umeda, Niigata-shi (JP)

(72) Inventors: Kenji Toda, Niigata-shi (JP); Kazuyoshi Uematsu, Niigata-shi (JP); Mineo Sato, Niigata-shi (JP); Tadashi Ishigaki, Niigata-shi (JP); Yoshitaka Kawakami, Niigata-shi (JP); Tetsu Umeda, Niigata-shi (JP)

(73) Assignees: SUMITOMO CHEMICAL COMPANY, LIMITED, Chuo-ku, Tokyo (JP); NIIGATA UNIVERSITY, Niigata-shi, Niigata (JP)

(21) Appl. No.: 13/990,839

(22) PCT Filed: Dec. 2, 2011
(86) PCT No.: PCT/JP2011/077950

§ 371 Date: Jul. 10, 2013

(30) Foreign Application Priority Data
Dec. 2, 2010 (JP) 2010-269355

(51) Int. Cl. H01L 33/50

(52) U.S. Cl. CPC H01L 33/502
USPC 257/98; 252/301.4 F

(57) ABSTRACT

A crystalline material represented by M¹₂ₐ(M²_{b}L_{c})M³_{d}O_{y}Nₓ wherein M¹ is at least one element selected from alkali metals, M² is at least one element selected from Ca, Sr, and Ba, M³ is at least one element selected from Si and Ge, L is at least one element selected from rare earth elements, Bi, and Mn, a is 0.9 to 1.5, b is 0.8 to 1.2, c is 0.005 to 0.2, d is 0.8 to 1.2, x is 0.001 to 1.0, and y is 3.0 to 4.0 or less.

### TECHNICAL FIELD

The present invention relates to a crystalline material, and particularly relates to a crystalline material that is a phosphor.

### BACKGROUND ART

Recently, white LEDs have been used in backlights for liquid crystal televisions and lightings, and their practical use has been developed. The white LED market has been rapidly expanding. The white LED is composed of a combination of an LED chip that emits the light in the ultraviolet to blue region (wavelength is approximately 380 to 500 nm) and a phosphor that is excited by the light emitted from the LED chip to emit light. It is able to attain Colors of white at various color temperatures based on the combination of the LED chip and the phosphor.

The phosphor that is excited by the light in the ultraviolet to blue region to emit light can be suitably used for the white LED. As the phosphor for the white LED, for example, a phosphor represented by Li₂SrSiO₄:Eu is disclosed in Patent Literatures 1 and 2.

### CITATION LIST

### Patent Literature

Patent Literature 1: International Publication No. WO 03/80763
Patent Literature 2: Japanese Patent Application Laid-Open No. 2006-237113

### SUMMARY OF INVENTION

### Technical Problem

However, for example, further improvement in light emission intensity is demanded of the phosphor such as Li₂SrSiO₄:Eu.

Moreover, for example, in the white LED, the phosphor is excited by the blue light emitted from a blue LED to emit light and to obtain the white light. However, it is known that the peak of the wavelength of the blue light emitted from the blue LED shifts due to deterioration of the blue LED. As the excitation spectrum of the phosphor is wider in the blue region, it is able to suppress deviation of the color of the white LED. Specifically, in the case where the excitation spectrum of the phosphor for the white LED is wide, for example, from 400 to 500 nm, it is able to suppress deviation of the color of the white LED.

An object of the present invention is to provide a crystalline material and phosphor that exhibit high light emission intensity (high luminance) and has a wide excitation spectrum. Also, an other object of the present invention is to provide a light-emitting apparatus that exhibits high luminance.

### Solution to Problem

One aspect of the present invention provides a crystalline material represented by M¹₂ₐ(M²_{b}L_{c})M³_{d}O_{y}Nₓ. M¹ is at least one element selected from alkali metals, M² is at least one element selected from Ca, Sr, and Ba, M³ is at least one element selected from Si and Ge, L is at least one element selected from rare earth elements, Bi, and Mn, a is 0.9 to 1.5 (0.9 or more and 1.5 or less), b is 0.8 to 1.2 (0.8 or more and 1.2 or less), c is 0.005 to 0.2 (0.005 or more and 0.2 or less), d is 0.8 to 1.2 (0.8 or more and 1.2 or less), x is 0.001 to 1.0 (0.001 or more and 1.0 or less), and y is 3.0 to 4.0 (3.0 or more and 4.0 or less). A crystalline material of the present invention is usually a phosphor.

In the above formula, y may be 4−3x/2. Moreover, L may be at least one element including Eu, selected from rare earth elements, Bi, and Mn and Eu may include divalent Eu. In M¹, M², and M³, M¹ may be Li, and M³ may be Si. Moreover, M² may be only Sr, may be Sr and Ca, or may be Sr and Ba.

Another aspect according to the present invention provides a light-emitting apparatus comprising a light-emitting device and the phosphor. The light-emitting device may be an LED. Further, another aspect according to the present invention provides a white LED comprising an LED and the phosphor.

### Advantageous Effect of Invention

The crystalline material according to the present invention can exhibit properties of a phosphor, has a wide excitation spectrum, and can exhibit high light emission intensity. For this reason, by applying the crystalline material to a light-emitting apparatus, it is able to attain a light-emitting apparatus with high light emission intensity (high luminance).

### BRIEF DESCRIPTION OF DRAWINGS

FIG. 1 is a sectional view showing one embodiment of a light-emitting apparatus.

FIG. 2 is a graph showing a light emission spectrum.

### DESCRIPTION OF EMBODIMENTS

The present embodiment relates to a crystalline material. The crystalline material usually exhibits the properties of a phosphor, and can be excited by the light in the blue region (peak wavelength is approximately 380 to 500 nm) to emit light of yellow (peak wavelength is approximately 560 to 590 nm). The crystalline material according to the present embodiment is represented by the formula: M¹₂ₐ(M²_{b}L_{c})M³_{d}O_{y}Nₓ. By preparing such a composition, the crystalline material according to the present embodiment has a wide excitation spectrum, and can attain high light emission intensity. In the above formula, M¹ represents at least one element selected from alkali metals, M² represents at least one element selected from Ca, Sr, and Ba, M³ represents at least one element selected from Si and Ge, L represents at least one element selected from rare earth elements, Bi, and Mn, a is 0.9 to 1.5 (0.9 or more and 1.5 or less), b is 0.8 to 1.2 (0.8 or more and 1.2 or less), c is 0.005 to 0.2 (0.005 or more and 0.2 or less), d is 0.8 to 1.2 (0.8 or more and 1.2 or less), x is 0.001 to 1.0 (0.001 or more and 1.0 or less), and y is 3.0 to 4.0 (3.0 or more and 4.0 or less).

M¹ is preferably one or two or more (particularly one) elements selected from Li, Na, and K, and more preferably Li.

M² is preferably only Sr (Sr alone), or a combination of Sr and other M² element, and particularly preferably Sr alone, a combination of Sr and Ca, or a combination of Sr and Ba. In this case, the contents of Sr, Ca, and Ba based on the total amount of Sr, Ca, and Ba are as follows in an atomic ratio: it is preferable that Sr be 0.5 to 1.0 (0.5≧Sr≧1.0), Ca be 0 to 0.5 (0≧Ca≧0.5), and Ba be 0 to 0.5 (0≧Ba≧0.5); more preferably, Sr is 0.7 to 1.0 (0.7≧Sr≧1.0), Ca is 0 to 0.3 (0≧Ca≧0.3), and Ba is 0 to 0.3 (0≧Ba≧0.3); and still more preferably, Sr is 0.95 to 1.0 (0.95≧Sr≧1.0), Ca is 0 to 0.05 (0≧Ca≧0.05), and Ba is 0 to 0.05 (0≧Ba≧0.05).

M³ is preferably Si. When M³ is Si, it is preferable that M¹ be Li.

L is an element to be doped as a light emission ion, and it is preferable that L contain at least Eu.

For example, L may be Eu alone, a combination of Eu and a rare earth element other than Eu, a combination of Eu and Bi, and a combination of Eu and Mn. Moreover, it is preferable that Eu as L includes at least divalent Eu (Eu²⁺), namely, it is preferable that Eu be only divalent Eu (Eu²⁺), or be a combination of divalent Eu (Eu²⁺) and trivalent Eu (Eu³⁺). When Eu as L includes divalent Eu (Eu²⁺), the crystalline material can be excited by the blue light to emit light of yellow. In the phosphor Li₂SrSiO₄:Eu disclosed in Patent Literature 1, Eu as L is only trivalent Eu (Eu³⁺), and the phosphor emits light of red.

The lower limit of a is 0.9 or more, and preferably 0.95 or more. Moreover, the upper limit of a is 1.5 or less, preferably 1.2 or less, more preferably 1.1 or less, and particularly preferably 1.05 or less.

The lower limit of b is 0.8 or more, and preferably 0.9 or more. Moreover, the upper limit of b is 1.2 or less, preferably 1.1 or less, and more preferably 1.05 or less.

The lower limit of c is 0.005 or more, preferably 0.01 or more, and more preferably 0.015 or more. Moreover, the upper limit of c is 0.2 or less, preferably 0.1 or less, and more preferably 0.05 or less.

The lower limits of a value of b+c and d may be the same or different, and are each preferably 0.9 or more, and more preferably 0.95 or more. The upper limits of a value of b+c and d may be the same or different, and are each preferably 1.1 or less, and more preferably 1.05 or less. In other words, the value of b+c and d may be the same or different, and preferably 0.9 to 1.1, more preferably 0.95 to 1.05, and still more preferably 1.

The ratio of a to b+c (a/(b+c)), the ratio of a to d (a/d), and the ratio of b+c to d ((b+c)/d) may be the same or different, and for example, are each 0.9 to 1.1, and preferably 0.95 to 1.05.

The lower limit of x is 0.001 or more, and preferably 0.01 or more. Moreover, the upper limit of x is 1.0 or less, preferably 0.5 or less, more preferably 0.1 or less, and still more preferably 0.08 or less.

The lower limit of y is 3.0 or more, preferably 3.5 or more, and more preferably 3.7 or more. Moreover, the upper limit of y is 4.0 or less, preferably 3.95 or less, and more preferably 3.9 or less.

It is preferable that y be 4−3x/2. The crystalline material according to the present embodiment and represented by the formula: M¹₂ₐ(M²_{b}L_{c})M³_{d}O_{y}Nₓ is generated by replacing part of oxygen by nitrogen during the production process. For this reason, it is preferable that ideally, y=4−3x/2. In the case where firing is performed in a reduction atmosphere, defect of anion may be caused, and therefore y=4−3x/2 may not be satisfied.

In the composition of the crystalline material according to the present embodiment, it is preferable that values of a, b+c, and d be within the range of 1±0.03, and it is particularly preferable that values of a, b+c, and d be 1. It is preferable that y be 4−3x/2, M¹ be L¹, M³ be Si, and M² be Sr alone, or Sr and Ca. Specifically, examples of the preferable composition of the crystalline material according to the present embodiment include Li_{1.96}Sr_{0.98}Eu_{0.02}SiO_{3.88}N_{0.08}.

The crystal system of the crystalline material according to the present embodiment is usually trigonal or hexagonal.

The crystalline material according to the present embodiment may contain a halogen element (one or more elements selected from F, Cl, Br, and I) derived from a raw material mixture described later (for example, in the case of using a halogen compound as a raw material). The amount of the halogen element in the crystalline material is usually the same amount as or less than the total amount of the halogen element(s) contained in the metal compound to be used as the raw material, preferably 50% or less, and more preferably 25% or less based on the total amount of the halogen element(s) contained in the metal compound to be used as the raw material.

Moreover, the crystalline material according to the present embodiment and other compound may be mixed to obtain a phosphor.

The crystalline material according to the present embodiment may be produced by (i) performing at least one time of firing in a nitriding atmosphere such as an atmosphere containing NH₃ gas, and/or (ii) using the raw material mixture containing a nitride or oxynitride in which the nitride or oxynitride is one or more compounds (hereinafter, these are referred to as a “nitrogen-containing compound”) selected from those containing one or more of M¹, M², M³, and L, in firing the raw material mixture containing M¹, M², M³, and L once or more.

Raw Material Mixture

More specifically, the raw material mixture is a mixture of a substance containing an element M¹ (first raw material), a substance containing an element M² (second raw material), a substance containing an element L (third raw material), and a substance containing an element M³ (fourth raw material). The elements M¹, M², L, and M³ each are a metal element; for this reason, herein, the first to fourth raw materials are referred to as a metal compound in some cases, and the mixture thereof is referred to as a metal compound mixture in some cases. Herein, the “metal element” is used as a meaning including a metalloid element such as Si and Ge. The metal compound may be an oxide of a metal M¹, M², L, or M³, or may be a substance that decomposes or oxidizes at a high temperature (particularly firing temperature) to form an oxide thereof. Examples of the substance that forms an oxide include hydroxides, nitrides, halides, oxynitrides, acid derivatives, and salts (such as carbonates, nitric acid salts, and oxalic acid salts).

The first raw material is preferably selected from hydroxides, oxides, carbonates, and nitrides of a metal M¹ (particularly lithium). Examples of a particularly preferable first raw material include lithium hydroxide (LiOH), lithium oxide (Li₂O), lithium carbonate (Li₂CO₃), or lithium nitride (Li₃N). Any of these first raw materials may be used alone or in combinations of two or more.

Examples of the second raw material include hydroxides, oxides, carbonates, or nitrides of a metal M² (particularly strontium, barium, and calcium, for example). More specifically, the second raw material is selected from strontium hydroxide (Sr(OH)₂), strontium oxide (SrO), strontium carbonate (SrCO₃), strontium nitride (Sr₃N₂), and calcium carbonate (CaCO₃). Any of these second raw materials may be used alone or in combinations of two or more.

It is preferable that the third raw material be a hydroxide, an oxide, a carbonate, a chloride, or a nitride of a metal L (particularly europium). The third raw material is selected from, for example, europium hydroxide (Eu(OH)₂, Eu(OH)₃), europium oxide (EuO, Eu₂O₃), europium carbonate (EuCO₃, Eu₂(CO₃)₃), europium chloride (EuCl₂, EuCl₃), europium nitrate (Eu(NO₃)₂, Eu(NO₃)₃), and europium nitride (Eu₃N₂, EuN). Any of these third raw materials may be used alone or in combinations of two or more.

The fourth raw material is preferably an oxide, acid derivative, salt, or nitride of a metal M³ (particularly silicon). Examples of a preferable fourth raw material include silicon dioxide, silicic acid, silicic acid salt, or silicon nitride.

Mixing of the first raw material to the fourth raw material may be performed by one of a wet method and a dry method. In the mixing, an ordinary apparatus may be used. Examples of such an apparatus include a ball mill, a V type mixer, and a stirrer.

Firing

The firing condition may be properly changed as long as the firing condition is a condition that allows the crystalline material to be obtained. The number of times of firing may be one or two or more, and preferably two or more. The firing atmosphere may be an inert gas atmosphere (such as nitrogen and argon), an oxidizing gas atmosphere (such as air, oxygen, and a mixed gas of oxygen and an inert gas), or a reducing gas atmosphere (such as a mixed gas of 0.1 to 10% by volume of hydrogen and an inert gas, NH₃ gas, and a mixed gas of 10 to less than 100% by volume of NH₃ gas and an inert gas), for example. The firing atmosphere may be pressurized, when necessary. The atmosphere can also be changed for each firing. However, it is preferable that at least one firing be performed in the nitriding atmosphere.

More preferably, the first firing is performed in a non-nitriding atmosphere, and the second or later firing is performed in a nitriding atmosphere. The non-nitriding atmosphere is, for example, an atmosphere that does not containin NH₃ gas, or an atmosphere that does not contain high pressure (approximately 0.1 to 5.0 MPa) N₂.

In the case where the raw material mixture does not contain nitrogen-containing compound, by doing as above, silicate or germanate represented by M¹₂ₐ(M²_{b}L_{c})M³_{d}O_{w} can be formed by the first firing. By performing the second or later firing in a nitriding atmosphere, nitrogen can be introduced into the silicate or germanate represented by M¹₂ₐ(M²_{b}L^{c})M³_{d}O_{w} to from a crystalline material represented by M¹₂ₐ(M²_{b}L_{c})M³_{d}O_{y}Nₓ.

In the case where the raw material mixture contains a nitrogen-containing compound, by doing as above, a compound represented by M¹₂ₐ(M²_{b}L_{c})M³_{d}O_{w}N_{z} can be formed by the first firing. By performing the second or later firing in a nitriding atmosphere, nitrogen can be introduced such that the compound represented by the M¹₂ₐ(M²_{b}L_{c})M³_{d}O_{w}N_{z} becomes a composition represented by M¹₂ₐ(M²_{b}L_{c})M³_{d}O_{y}Nₓ. In the compositional formula above, y<w, and x>z. Moreover, it is preferable that w=4−3/2×z. Similarly to the relationship between x and y described above, w=4−3/2×z may not be satisfied, however.

In the case where the raw material mixture contains the nitrogen-containing compound, however, the firing in the nitriding atmosphere may not always be performed, and only the firing in the non-nitriding atmosphere may be performed. In this case, by adjusting the amount of the nitrogen-containing compound in the raw material mixture, the amount of nitrogen in the crystalline material represented by M¹₂ₐ(M²_{b}L_{c})M³_{d}O_{y}Nₓ may be controlled.

Examples of the gas for providing the nitriding atmosphere include NH₃ gas (100% by volume), a mixed gas of not less than 10% by volume and less than 100% by volume of NH₃ gas and an inert gas, and high pressure (approximately 0.1 to 5.0 MPa) nitrogen gas. The gas for providing the nitriding atmosphere is preferably NH₃ gas (100% by volume) or a mixed gas of not less than 50% by volume and less than 100% by volume of NH₃ gas and an inert gas.

The firing temperature is usually 700 to 1000° C., preferably 750 to 950° C., and more preferably 800 to 900° C. The firing time is usually 1 to 100 hours, preferably 10 to 90 hours, and more preferably 20 to 80 hours.

In the case where the raw material mixture is fired in a strong reducing atmosphere, a proper amount of carbon may be added to the metal compound, and firing may be performed. Moreover, in the case where the raw material mixture is fired in an inert atmosphere or in an oxidizing atmosphere, it is preferable that firing be subsequently performed in a reducing atmosphere.

In the case where a hydroxide, a carbonate, a nitric acid salt, a halide, or an oxalic acid salt is used as the metal compound, the method for producing a crystalline material according to the present embodiment may further comprise a step of calcining these metal compounds before firing the raw material mixture or before mixing the metal compounds. By keeping the metal compound at 500 to 800° C. for approximately 1 to 100 hours (preferably 10 to 90 hours), for example, the metal compound may be calcined.

In the calcination or firing, a reaction accelerator can be added to the metal compound or a mixture of these. Namely, the calcination or firing may be performed in the presence of the reaction accelerator. By adding the reaction accelerator, the light emission intensity of the crystalline material can be increased. The reaction accelerator is selected from, for example, alkali metal halides, alkali metal carbonates, alkali metal hydrogencarbonates, halogenated ammonium, oxide of boron (B₂O₃), and oxo acid of boron (H₃BO₃). The alkali metal halide is preferably fluorides of alkali metals or chlorides of alkali metals, and LiF, NaF, KF, LiCl, NaCl, or KCl, for example. The alkali metal carbonates are Li₂CO₃, Na₂CO₃, or K₂CO₃, for example. The alkali metal hydrogencarbonate is NaHCO₃, for example. The ammonium halide is NH₄Cl or NH₄I, for example.

The calcined product or the fired products after the respective firings may be subjected to one or more treatments such as crushing, mixing, washing, and classification, when necessary. A ball mill, a V type mixer, a stirrer, and a jet mill can be used in crushing and mixing, for example.

In order to obtain the crystalline material M¹₂ₐ(M²_{b}L_{c})M³_{d}O_{y}Nₓ, the mixing proportion of the metal compound may be adjusted such that the ratio (M¹ element):(M² element):(L element):(M³ element) is 2a:b:c:d, and the firing time under a nitriding atmosphere may be adjusted. Moreover, in the case where the raw material mixture contains the nitrogen-containing compound, by adjusting the amount of these to be used and the firing condition (such as firing time) under the nitriding atmosphere, the content of nitrogen in the crystalline material (value of x) may be adjusted. Moreover, the content of oxygen in the crystalline material (value of y) can be controlled by adjusting the firing condition under an O₂ containing atmosphere (such as O₂ concentration in the firing atmosphere, and the firing time under the O₂ containing atmosphere).

A crystalline material according to the present embodiment can exhibit properties of a phosphor. The crystalline material has a wide excitation spectrum suitable for the white LED. The crystalline material can exhibit the light emission intensity higher than that of Li₂SrSiO₄:Eu by exciting the crystalline material by the blue light. In the crystalline material according to the present embodiment, the ratio of the light emission intensity (2) at excitation by the light with a wavelength of 500 nm to the light emission intensity (1) at excitation by the light with a wavelength of 450 nm (light emission intensity (2)/light emission intensity (1)) is 80% or more, preferably 85% or more, and more preferably 90% or more. Accordingly, the crystalline material according to the present embodiment can be suitably used in the light-emitting apparatus (such as the white LED). The light-emitting apparatus according to the present embodiment includes a light-emitting device (exciting source) and a phosphor. The white LED according to the present embodiment comprises an LED and a phosphor. The phosphor is the crystalline material according to the present embodiment. It is preferable that the light-emitting device be an LED.

The white LED will be described in more detail. The white LED is usually composed of a light-emitting device (LED chip) that emits the ultraviolet to blue light (wavelength is approximately 200 to 500 nm, and preferably approximately 380 to 500 nm) and a fluorescent layer including a phosphor. The white LED can be produced, for example, by the methods disclosed in Japanese Patent Application Laid-Open Nos. 11-31845 and 2002-226846. Namely, for example, the white LED can be produced by the method in which the light-emitting device is sealed with a light-transmittable resin such as an epoxy resin and a silicone resin, and the surface thereof is covered with the phosphor. If the amount of the phosphor is properly set, the white LED is formed to emit the light of a desired white color.

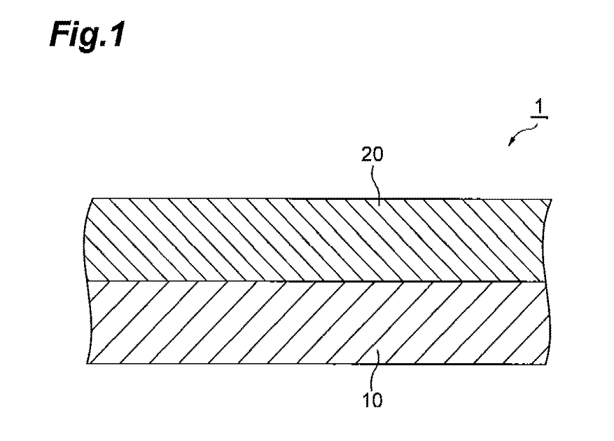

FIG. 1 is a sectional view showing one embodiment of the light-emitting apparatus. A light-emitting apparatus 1 shown in FIG. 1 includes a light-emitting device 10, and a fluorescent layer 20 provided on the light-emitting device 10. The phosphor that forms the fluorescent layer 20 receives the light from the light-emitting device 10 to be excited and emit fluorescence. By properly setting the kind, amount, and the like of the phosphor that forms the fluorescent layer 20, white light emission can be obtained. Namely, a white LED can be formed. The light-emitting apparatus or white LED according to the present embodiment is not limited to the form shown in FIG. 1, and can be properly modified without departing from the gist of the present invention.

As the phosphor, the crystalline material according to the present embodiment may be contained alone, or other phosphor may be further contained. The other phosphor is selected from, for example, BaMgAl₁₀O₁₇:Eu, (Ba,Sr, Ca)(Al,Ga)₂S₄:Eu, BaMgAl₁₀O₁₇:(Eu,Mn), BaAl₁₂O₁₉:(Eu,Mn), (Ba,Sr, Ca)S:(Eu,Mn), YBO₃:(Ce,Tb), Y₂O₃:Eu, Y₂O₂S:Eu, YVO₄:Eu, (Ca,Sr)S:Eu, SrY₂O₄:Eu, Ca—Al—Si—O—N:Eu, (Ba,Sr, Ca)Si₂O₂N₂:Eu, β-sialon, CaSc₂O₄:Ce, and Li—(Ca,Mg)-Ln-Al—O—N:Eu (wherein Ln represents a rare earth element other than Eu).

Examples of the light-emitting device that emits light with a wavelength of 200 nm to 500 nm include ultraviolet LED chips blue LED chips and the like. In these LED chips, a semiconductor having a layer of GaN, (0<i<1), InᵢAlⱼGa₁₋ᵢ₋ⱼN (0<i<1, 0<j<1, i+j<1) is used as the light emitting layer. By changing the composition of the light emitting layer, the light emission wavelength can be changed.

The crystalline material according to the present embodiment can also be used in the light-emitting apparatus other than the white LED, for example, light-emitting apparatuses whose phosphor exciting source is vacuum ultraviolet light (such as PDP); light-emitting apparatuses whose phosphor exciting source is ultraviolet light (such as backlights for liquid crystal displays and three band fluorescent lamps); and light-emitting apparatuses whose phosphor exciting source is an electron beam (such as CRT and FED).

### EXAMPLES

Hereinafter, the present invention will be more specifically described using Examples. The present invention will not be limited by Examples below. The present invention, of course, can be implemented by an aspect to which proper modifications are added within the range in which the modifications can be complied with the gist described above and that described later, and those modifications are included in the technical scope of the present invention.

The light emission intensity of the crystalline material obtained in Examples below was determined using a fluorescence spectrometer (made by JASCO Corporation, FP-6500). For X-ray diffraction (XRD) measurement of the crystalline material, an X-ray diffractometer (made by Rigaku Corporation, RINT2000) was used. The valency proportion of Eu in the crystalline material was evaluated by X-ray absorption fine structure (XAFS) measurement.

XAFS measurement was performed in the SPring-8 using a beam line BL14B2 according to a transmission method. The Eu-L3 absorption edge of 6650 to 7600 eV was the measurement region. As the standard sample of Eu²⁺ (6972 eV), BaMgAl₁₀O₁₇:Eu²⁺ (BAM) was used. As the standard sample of Eu³⁺ (6980 eV), europium oxide (made by Shin-Etsu Chemical Co., Ltd., purity of 99.99%) was used. The X-ray absorption near edge structure (XANES) spectrum was obtained using an analyzing program (made by Rigaku Corporation, REX2000) by processing the XAFS data of the samples based on the background. Subsequently, using the XANES spectra of the Eu²⁺ standard sample and the Eu³⁺ standard sample, pattern fitting of the XANES spectra of the samples were performed, and the proportion of Eu²⁺ in the sample was calculated from the proportion of Eu²⁺ peaks.

The contents of oxygen and nitrogen in the crystalline material were measured using an EMGA-920 made by HORIBA, Ltd. For the content of oxygen, a non-dispersive infrared absorption method was used. For the content of nitrogen, a thermal conductivity method was used.

### Example 1

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 1.96:0.98:0.02:1.0, and these were mixed with a dry ball mill for 6 hours to obtain a metal compound mixture.

The mixture was fired in the air at 750° C. for 10 hours, and then gradually cooled to room temperature. The obtained fired product was crushed, and fired under the NH₃ gas atmosphere at 800° C. for 3 hours to obtain a crystalline compound (crystalline material) represented by the formula Li_{1.96}Sr_{0.98}Eu_{0.02}SiO_{3.99}N_{0.005}.

### Example 2

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 1.96:0.98:0.02:1.0, and these were mixed with a dry ball mill for 6 hours to obtain a metal compound mixture.

The mixture was fired in the air at 750° C. for 10 hours, and then gradually cooled to room temperature. The obtained fired product was crushed, and fired under the NH₃ gas atmosphere at 800° C. for 6 hours to obtain a crystalline compound (crystalline material) represented by the formula Li_{1.96}Sr_{0.98}Eu_{0.02}SiO_{3.98}N_{0.010}.

### Example 3

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 1.96:0.98:0.02:1.0, and these were mixed with a dry ball mill for 6 hours to obtain a metal compound mixture.

The mixture was fired in the air at 750° C. for 10 hours, and then gradually cooled to room temperature. The obtained fired product was crushed, and fired under the NH₃ gas atmosphere at 800° C. for 12 hours to obtain a crystalline compound (crystalline material) represented by the formula Li_{1.96}Sr_{0.98}EU_{0.02}SiO_{3.92}N_{0.053}.

### Example 4

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 1.96:0.98:0.02:1.0, and these were mixed with a dry ball mill for 6 hours to obtain a metal compound mixture.

The mixture was fired in the air at 750° C. for 10 hours, and then gradually cooled to room temperature. The obtained fired product was crushed, and fired under the NH₃ gas atmosphere at 800° C. for 24 hours to obtain a crystalline compound (crystalline material) represented by the formula Li_{1.96}Sr_{0.98}Eu_{0.02}SiO_{3.88}N_{0.082}.

### Example 5

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 1.96:0.98:0.02:1.0, and these were mixed with a dry ball mill for 6 hours to obtain a metal compound mixture.

The mixture was fired under the NH₃ gas atmosphere at 800° C. for 12 hours to obtain a crystalline compound (crystalline material) represented by the formula Li_{1.96}Sr_{0.98}Eu_{0.02}SiO_{3.97}N_{0.022}.

### Example 6

Lithium carbonate (made by KANTO CHEMICAL CO., INC., purity of 99%), strontium carbonate (made by Sakai Chemical Industry Co., Ltd., purity of 99% or more), calcium carbonate (made by Ube Material Industries, Ltd., purity of 99.99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Ca:Eu:Si was 1.96:0.97:0.01:0.02:1.0, and these were mixed with a dry ball mill for 6 hours to obtain a metal compound mixture.

The mixture was fired in the air at 750° C. for 10 hours, and then gradually cooled to room temperature. The obtained fired product was crushed, and fired under the NH₃ gas atmosphere at 800° C. for 12 hours to obtain a crystalline compound (crystalline material) represented by the formula Li_{1.96}Sr_{0.97}Ca_{0.01}Eu_{0.02}SiO_{3.93}N_{0.046}.

### Example 7

Lithium carbonate (made by KANTO CHEMICAL CO., INC., purity of 99%), strontium carbonate (made by Sakai Chemical Industry Co., Ltd., purity of 99% or more), barium carbonate (made by KANTO CHEMICAL CO., INC., purity of 99.9%), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Ba:Eu:Si was 1.96:0.97:0.01:0.02:1.0, and these were mixed with a dry ball mill for 6 hours to obtain a metal compound mixture.

The mixture was fired in the air at 750° C. for 10 hours, and then gradually cooled to room temperature. The obtained fired product was crushed, and fired under the NH₃ gas atmosphere at 800° C. for 12 hours to obtain a crystalline compound (crystalline material) represented by the formula Li_{1.96}Sr_{0.97}Ba_{0.01}Eu_{0.02}SiO_{3.94}N_{0.040}.

Crystalline materials in Examples 8 to 10 were obtained in the same manner as in Example 3 except that the proportions (atomic ratios) of Eu and Sr in the raw material were changed such that the compositional formula shown in Table 1 was attained.

Crystalline materials in Examples 11 to 13 were obtained in the same manner as in Example 3 except that the proportion (atomic ratio) of Li in the raw material was changed such that the compositional formula shown in Table 1 was attained.

Crystalline materials in Examples 14 to 16 were obtained in the same manner as in Example 6 except that the proportions (atomic ratios) of Ca and Sr in the raw material were changed such that the compositional formula shown in Table 1 was attained.

Crystalline materials in Examples 17 to 19 were obtained in the same manner as in Example 7 except that the proportions (atomic ratios) of Ba and Sr in the raw material were changed such that the compositional formula shown in Table 1 was attained.

In Examples 8 to 19, the proportions (atomic ratios) of the M¹ element, the M² element, the L element, and the M³ element in the raw material are the same atomic ratio of these elements in the compositional formula shown in Table 1.

### Comparative Example 1

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 1.96:0.98:0.02:1.0, and these were mixed with a dry ball mill for 6 hours to obtain a metal compound mixture.

The mixture was fired under the mixed gas atmosphere of N₂ and 5% by volume of H₂ at 800° C. for 24 hours, and then gradually cooled to room temperature to obtain a crystalline compound represented by the formula Li_{1.96}(Sr_{0.98}Eu_{0.02})SiO_{4.00}.

### Comparative Example 2

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 1.96:0.98:0.02:1.0, and these were mixed with a dry ball mill for 6 hours to obtain a metal compound mixture.

The mixture was fired under the mixed gas atmosphere of N₂ and 5% by volume of H₂ at 800° C. for 24 hours, and then gradually cooled to room temperature. The obtained fired product was crushed, and fired under the mixed gas atmosphere of N₂ and 5% by volume of H₂ at 800° C. for 24 hours to obtain a crystalline compound represented by the formula Li_{1.96}(Sr_{0.98}Eu_{0.02})SiO_{4.00}.

### Comparative Example 3

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 1.96:0.98:0.02:1.0, and these were mixed with a dry ball mill for 6 hours to obtain a metal compound mixture.

The mixture was fired in the air at 750° C. for 10 hours, and then gradually cooled to room temperature. The obtained fired product was crushed, and fired under the mixed gas atmosphere of N₂ and 5% by volume of H₂ at 800° C. for 24 hours to obtain a crystalline compound represented by the formula Li_{1.96}(Sr_{0.98}Eu_{0.02})SiO_{4.00}.

### Comparative Example 4

Lithium carbonate (made by KANTO CHEMICAL CO., INC., purity of 99%), strontium carbonate (made by Sakai Chemical Industry Co., Ltd., purity of 99% or more), europium oxide (made by Shin-Etsu Chemical Co., Ltd., purity of 99.99%), and silicon dioxide (made by Nippon Aerosil Co., Ltd.: purity of 99.99%) were weighed such that the atomic ratio of Li:Sr:Eu:Si was 2.00:0.98:0.02:1.0, and these were mixed with a dry ball mill for 6 hours to obtain a metal compound mixture.

The mixture was fired in the air at 750° C. for 10 hours, and then gradually cooled to room temperature. The obtained fired product was crushed, and fired under the mixed gas atmosphere of N₂ and 5% by volume of H₂ at 800° C. for 24 hours to obtain a compound represented by the formula Li_{2.00}(Sr_{0.98}Eu_{0.02})SiO_{4.00}.

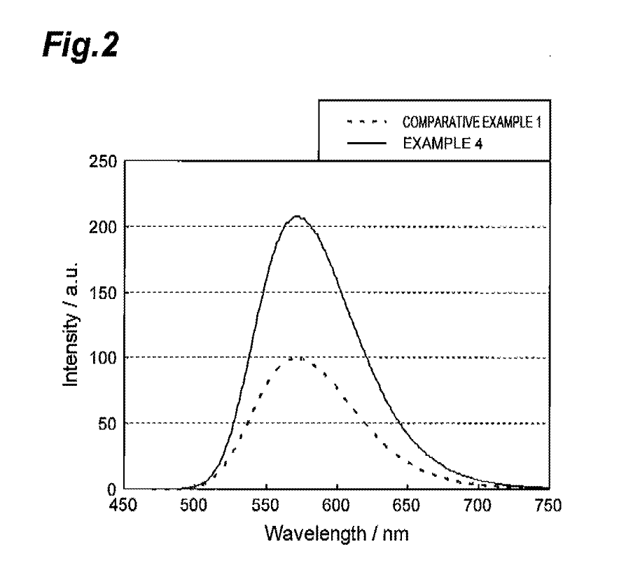

The properties of the crystalline materials obtained in Examples 1 to 19 and Comparative Examples 1 to 4 are shown in Table 1. The light emission intensity (1) designates the peak intensity of the light emission spectrum when the crystalline material is excited by the light with a wavelength of 450 nm, and the light emission intensity (2) designates the peak intensity of the light emission spectrum when the crystalline material is excited by the light with the wavelength of 500 nm. The light emission intensities (1) and (2) each are expressed as a relative value when the light emission intensity (1) in Comparative Example 1 is 100. Moreover, the light emission spectrum in Example 4 and that in Comparative Example 1 are shown in FIG. 2.

TABLE 1

| | | | Light | | | | |
|---|---|---|---|---|---|---|---|
| | Light | Light | emission | | | | |
| | emission | emission | intensity | | | | |
| | intensity | intensity | (2) × 100/ | Peak | Proportion | | |
| | (1) | (2) | light emission | wave- | of Eu²⁺ in | | |
| | (excited | (excited | intensity | length | total Eu | Value | |
| | at 450 nm) | at 500 nm) | (1) (%) | (nm) | (atomic %) | of x | Compositional formula: M¹₂ₐ(M²_{b}L_{c})M³_{d}O_{y}Nₓ |
| Example 1 | 123 | 103 | 84 | 570 | 41 | 0.005 | Li(1.96)Sr(0.98)Eu(0.02)SiO(3.99)N(0.005) |
| Example 2 | 133 | 126 | 95 | 570 | 46 | 0.010 | Li(1.96)Sr(0.98)Eu(0.02)SiO(3.98)N(0.010) |
| Example 3 | 183 | 182 | 99 | 570 | 56 | 0.053 | Li(1.96)Sr(0.98)Eu(0.02)SiO(3.92)N(0.053) |
| Example 4 | 207 | 205 | 99 | 571 | 88 | 0.082 | Li(1.96)Sr(0.98)Eu(0.02)SiO(3.88)N(0.082) |
| Example 5 | 106 | 106 | 100 | 571 | 70 | 0.022 | Li(1.96)Sr(0.98)Eu(0.02)SiO(3.97)N(0.022) |
| Example 6 | 150 | 127 | 85 | 571 | 55 | 0.046 | Li(1.96)Sr(0.97)Ca(0.01)Eu(0.02)SiO(3.93)N(0.046) |
| Example 7 | 147 | 124 | 84 | 571 | 54 | 0.040 | Li(1.96)Sr(0.97)Ba(0.01)Eu(0.02)SiO(3.94)N(0.040) |
| Example 8 | 156 | 156 | 100 | 570 | 56 | 0.062 | Li(1.96)Sr(0.99)Eu(0.01)SiO(3.91)N(0.062) |
| Example 9 | 177 | 176 | 99 | 570 | 59 | 0.056 | Li(1.96)Sr(0.97)Eu(0.03)SiO(3.91)N(0.056) |
| Example 10 | 142 | 144 | 101 | 570 | 25 | 0.050 | Li(1.96)Sr(0.95)Eu(0.05)SiO(3.93)N(0.050) |
| Example 11 | 166 | 160 | 96 | 570 | 48 | 0.050 | Li(1.90)Sr(0.98)Eu(0.02)SiO(3.93)N(0.050) |
| Example 12 | 183 | 180 | 98 | 570 | 55 | 0.052 | Li(2.00)Sr(0.98)Eu(0.02)SiO(3.92)N(0.052) |
| Example 13 | 170 | 167 | 98 | 570 | 46 | 0.052 | Li(2.05)Sr(0.98)Eu(0.02)SiO(3.92)N(0.052) |
| Example 14 | 140 | 120 | 86 | 570 | 42 | 0.038 | Li(1.96)Sr(0.93)Ca(0.05)Eu(0.02)SiO(3.94)N(0.038) |
| Example 15 | 123 | 109 | 89 | 571 | 35 | 0.035 | Li(1.96)Sr(0.88)Ca(0.10)Eu(0.02)SiO(3.95)N(0.035) |
| Example 16 | 113 | 99 | 88 | 572 | 33 | 0.035 | Li(1.96)Sr(0.68)Ca(0.30)Eu(0.02)SiO(3.94)N(0.035) |
| Example 17 | 137 | 119 | 87 | 569 | 42 | 0.030 | Li(1.96)Sr(0.93)Ba(0.05)Eu(0.02)SiO(3.95)N(0.030) |
| Example 18 | 132 | 108 | 82 | 567 | 35 | 0.028 | Li(1.96)Sr(0.88)Ba(0.10)Eu(0.02)SiO(3.96)N(0.028) |
| Example 19 | 122 | 95 | 78 | 566 | 35 | 0.020 | Li(1.96)Sr(0.68)Ba(0.30)Eu(0.02)SiO(3.97)N(0.020) |
| Comparative | 100 | 74 | 74 | 570 | 14 | <0.001 | Li(1.96)Sr(0.98)Eu(0.02)SiO(4.00) |
| Example 1 | | | | | | | |
| Comparative | 104 | 77 | 74 | 570 | 17 | <0.001 | Li(1.96)Sr(0.98)Eu(0.02)SiO(4.00) |
| Example 2 | | | | | | | |
| Comparative | 82 | 60 | 73 | 570 | 7 | <0.001 | Li(1.96)Sr(0.98)Eu(0.02)SiO(4.00) |
| Example 3 | | | | | | | |
| Comparative | 96 | 70 | 73 | 571 | 12 | <0.001 | Li(2.00)Sr(0.98)Eu(0.02)SiO(4.00) |
| Example 4 | | | | | | | |

Light emission intensities (1) and (2) each are a relative value when the light emission intensity (1) in Comparative Example 1 is 100.
The values of 2a, b, c, x, and y in the compositional formulas in Examples and Comparative Examples are written with brackets. Moreover, the value of d is 1 in each formula.

From Table 1, in the crystalline materials obtained in Examples 1 to 19, both of the light emission intensities (1) and (2) are higher than those of the crystalline materials obtained in Comparative Examples 1 to 4. Moreover, in the crystalline materials obtained in Comparative Examples 1 to 4, the light emission intensity (2) reduced to less than 75% of the light emission intensity (1), while in the crystalline materials obtained in Examples 1 to 19, the light emission intensity (2) was equal to the light emission intensity (1), or if reduced, was 75% or more (preferably 80% or more). Namely, it turned out that in the crystalline materials obtained in Examples 1 to 19, reduction in the light emission intensity can be suppressed even if the excitation wavelength is deviated.

### INDUSTRIAL APPLICABILITY

The crystalline material according to the present invention can exhibit the properties of the phosphor, has a wide excitation spectrum in the blue region, and exhibits high light emission intensity by excitation by the blue light; accordingly, the crystalline material is suitably used in the phosphor unit for the light-emitting apparatus represented by the white LED.

### REFERENCE SIGNS LIST

1 . . . light-emitting apparatus, 10 . . . light-emitting device, 20 . . . fluorescent layer.

1. A crystalline material represented by M¹₂ₐ(M²_{b}L_{c})M³_{d}O_{y}Nₓ, wherein
M¹ is at least one element selected from alkali metals,
M² is at least one element selected from Ca, Sr, and Ba,
M³ is at least one element selected from Si and Ge,
L is at least one element selected from rare earth elements, Bi, and Mn,
a is 0.9 to 1.5,
b is 0.8 to 1.2,
c is 0.005 to 0.2,
d is 0.8 to 1.2,
x is 0.001 to 1.0, and
y is 3.0 to 4.0.

2. The crystalline material according to claim 1, wherein L is at least one element including Eu, selected from rare earth elements, Bi, and Mn.

3. The crystalline material according to claim 2, wherein L is at least one element including divalent Eu, selected from rare earth elements, Bi, and Mn.

4. The crystalline material according to claim 1, wherein M¹ is Li, and M³ is Si.

5. The crystalline material according to claim 1, wherein M² is only Sr, is Sr and Ca, or is Sr and Ba.

6. The crystalline material according to claim 1, wherein y is 4−3x/2.

7. The crystalline material according to claim 1, wherein the crystalline material is a phosphor.

8. A light-emitting apparatus comprising
a light-emitting device, and
the phosphor according to claim 7.

9. The light-emitting apparatus according to claim 8, wherein the light-emitting device is an LED.

10. A white LED comprising
an LED, and
the phosphor according to claim 7.
